(19) United States
(12) Patent Application Publication
(10) Pub. No.: US 2006/0164177 A1
(43) Pub. Date: Jul. 27, 2006

(54) Signal-selecting circuit and real time clock device

(76) Inventor: Toru Shirotori, Minami-Minowa (JP)

Correspondence Address: HARNESS, DICKEY & PIERCE, P.L.C., P.O. BOX 828, BLOOMFIELD HILLS, MI, 48303, US

(21) Appl. No.: 11/304,978

(22) Filed: Dec. 15, 2005

(30) Foreign Application Priority Data
Dec. 16, 2004 (JP) 2004-364107
Dec. 5, 2005 (JP) 2005-350232

(51) Int. Cl. H03B 1/00

(52) U.S. Cl. 331/74

(57) ABSTRACT

A signal-selecting circuit applicable to low-active and high-active electronic circuits has a pull-up circuit and a pull-down circuit with one end of each connected to an input port. The pull-up circuit includes a first resistor and a first switch circuit connected serially. The remaining end of the pull-up circuit is connected to a power source. The pull-down circuit includes a second resistor and a second switch circuit connected serially. The remaining end of the pull-down circuit is connected to ground. The first switch circuit and second switch circuit are connected to a selecting part. The selecting part turns on-either the first switch circuit or the second switch circuit to fix the potential of the input port at a High state or a Low state according to an input selecting signal.

### BACKGROUND OF THE INVENTION

1. Technical Field

The present invention relates to a signal-selecting circuit. It relates to a signal-selecting circuit that is operable to select a signal at a low or high voltage level and input the signal to an electronic circuit and a-real time-clock device.

2. Related Art

Electronic devices equipped with a digital electronic circuit include low-active ones that work according to the negative logic in which its low voltage level state is “1” and its high voltage level state is “0,” and high-active ones that work according to the positive logic reversely in which its high voltage level state is “1” and its low voltage level state is “0.” Further, in an electronic device, a low-active circuit and a high-active circuit are often mixed.

Therefore, in regard to an electronic circuit such as an integrated circuit that constitutes an electronic device, generally in the case of a low-active electronic circuit, an input terminal (input port) is connected to a power source through a pull-up resistor to fix the potential of the input terminal at High. In contrast, in the case of a high-active electronic circuit, the input terminal is connected to the ground through a pull-down resistor to fix the potential of the input terminal at Low. This is because the input potential of the electronic circuit is unstable when nothing is input to the input terminal in the condition where the input terminal is electrically floating, namely when it stays in its high impedance state.

Which of Low or High of an input signal is made active depends on an electronic device (system). Therefore, it is desirable that a general-purpose device such as an integrated circuit support any case of making Low active and making High active. However, in the past devices supporting either the way of making Low active or the way of making High active according to specifications of each system have been fabricated, and there have been no devices supporting both ways.

Patent document JP-A-05-259876 discloses an IC chip having a pull-up circuit or a pull-down circuit formed therein, wherein one end of the pull-up circuit or pull-down circuit is connected to a control terminal of the IC chip, and the pull-up circuit or pull-down circuit can be switched between Enable or Disable from the outside through the control terminal.

However, either the pull-up circuit or pull-down circuit is provided in the IC chip described in JP-A-05-259876. Therefore, even when IC chips having the same function are manufactured, it is required to separately fabricate an IC chip including a pull-up circuit applied to a low-active system and an IC chip including a pull-down circuit applied to a high-active system, and such IC chips are inadequate as general purpose devices. In addition, devices for a low-active system and a high-active system are fabricated and as such, the management of fabrication processes is made complicated and inventory management is made troublesome. Generally, pull-up and pull-down circuits are accompanied by the generation of electric current because of their configuration. Therefore, steps have to be taken to avoid an unexpected increase in electric current consumption that can be caused by malfunction or the like.

The invention was made to overcome the disadvantages in the art. It is an object of the invention to enable a device to be applied to any of a low-active electronic circuit and a high-active electronic circuit. In addition, it is another object to minimize redundant current generation to detect an input signal with high accuracy.

### SUMMARY

To achieve the objects, a signal-selecting circuit in association with the invention includes: a pull-up circuit having a first resistive element and a first switch part connected in series with the first resistive element, and one end connected to an input terminal of an electronic circuit and the other end connected to a power source; a pull-down circuit having a second resistive element and a second switch part connected in series with the second resistive element, and one end connected to the input terminal and the other end connected to a ground; and a selecting part that turns on either the first or second switch part depending on a selecting signal input thereto.

In the invention thus arranged, when the first switch, part is turned on through the selecting part, the input terminal is connected to the power source, and then the potential of the input terminal is fixed at High. Accordingly, when a low voltage level signal (Low) is input to the input terminal, the potential of the input terminal lowers. Thus, it is possible to find the input of a low signal, and therefore the application to a low-active electronic circuit is made possible. On the other hand, when the second switch part is turned on through the selecting part, the input terminal is connected to the ground, whereby the potential is fixed at Low. Accordingly, in this case, the application to a high-active electronic circuit is made possible. In other words, the signal-selecting circuit can be applicable to any of low-active and high-active electronic circuits, and therefore it is possible to provide an input port having extremely high general versatility. In addition., it can support any of low-active and high-active electronic circuits and as such, the management of its fabrication processes and inventory management can be facilitated.

The selecting part may be connected to a setting-cancel part that outputs a cancel signal serving to turn off the switch part, which has been turned on, according to an input-sensing signal issued when the electronic circuit senses signal input to the input terminal. Thus, the following are made possible: to prevent e.g. the situation where the switch is needlessly depressed for a long time or an abnormal event in a system from causing a current to continue to flow; and to prevent battery drain in a portable electronic system. Further, the setting-cancel part may have a delay circuit that delays the input-sensing signal output by the electronic circuit by a predetermined length of time to output the cancel signal. Thus, the signal-selecting circuit can be applied to, for example, the case where it is desired to start or terminate the processing a given length of time later than the input of an input signal. Reversely, for the purpose of giving the effect of suppression of current top priority, it is possible to immediately cancel the setting with no delay. Therefore, the range of its applications can be made remarkably wide.

The delay circuit may be arranged so as to delay the input-sensing signal input therein to output the cancel signal based on a clock signal output by an oscillator circuit that the electronic circuit has therein. This eliminates the need for specially providing an oscillator circuit for measurement of delay time, and therefore makes its production cost less expensive and hardly increases the power consumption thereof.

A real time clock device in association with the invention includes: any one of the signal-selecting circuits; and an oscillator circuit. Thus, effects and advantages as described above can be achieved. Also, the real time clock device may be arranged so as to have: a divider part that converts an original oscillation clock signal output by the oscillator circuit into clock signals differing in cycle from each other and outputs the clock signals; a clock signal selecting part provided on an output side of the divider part, which outputs a clock signal of an arbitrary cycle output by the divider part to the delay circuit based on an input clock-selecting signal. By selecting and using clock signals of different cycles output by the divider part, it becomes possible to set a delay time arbitrarily.

### BRIEF DESCRIPTION OF THE DRAWINGS

FIG. 1 is a circuit diagram of a signal-selecting circuit in association of the first embodiment of the invention.

FIG. 2 is a block diagram of a part of a real time clock device including the signal-selecting circuit in association with the second embodiment.

FIG. 3 is a block diagram of a part of another real time clock device in association with the third embodiment.

FIG. 4 is a timing chart of assistance in explaining the operation of detecting switch input by a switch input-detection circuit in the third embodiment.

FIG. 5 is a timing chart of assistance, in explaining the operation of absorbing the chattering by the switch input-detection circuit in the third embodiment.

FIG. 6 is an entire block diagram showing an example of the real time clock device in association with the embodiment.

### BEST MODE FOR CARRYING OUT THE INVENTION

Preferred embodiments of a signal-selecting circuit and a real time clock device in association with the invention will be described in detail with reference to the accompanying drawings.

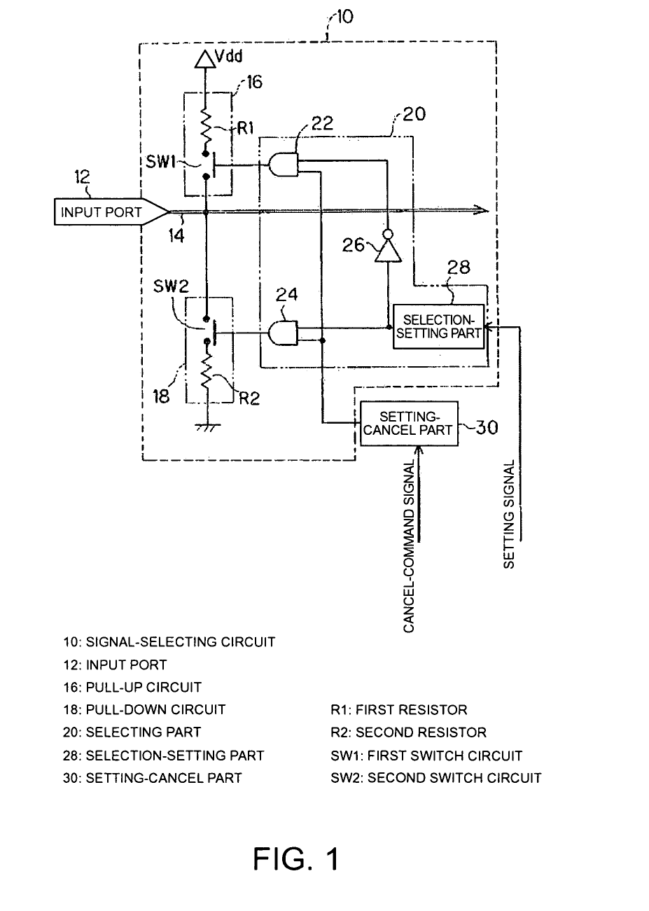

FIG. 1 represents a circuit diagram of a signal-selecting circuit in association with the first embodiment of the invention. The signal-selecting circuit 10 in FIG. 1 is formed in e.g. an integrated circuit that constitutes an electronic device, and it has an input port 12 as an input terminal. To the input port 12 is connected a signal line 14 that directs an input signal input to the input port 12 from the outside toward an electronic circuit (not shown) such as a CPU or arithmetic circuit. Also, a pull-up circuit 16 and a pull-down circuit 18 are connected to the signal line 14, therefore to the input port 12.

The pull-up circuit 16 includes a first resistor R1 as a first resistive element and a first switch circuit SW1 as a first switch part, which are connected in series. The first switch circuit SW1 has one contact making one end of the pull-up circuit 16, which is connected to the signal line 14. Also, the first switch circuit SW1 has the other contact connected to one terminal of the first resistor R1. The other terminal of the first resistor R1 makes the other end of the pull-up circuit 16, and is connected to a power source Vdd.

On the other hand, the pull-down circuit 18 has a second resistor R2 as a second resistive element and a second switch circuit SW2 as a second switch part, which are connected in series. The second switch circuit SW2 has one contact making one end of the pull-down circuit 18, which is connected to the signal line 14. Also, the second switch circuit SW2 has the other contact connected to one terminal of the second resistor R2. The other terminal of the second resistor R2 makes the other end of the pull-down circuit 18 and is connected to the ground. Now, in the case of the embodiment, the first switch circuit SW1 and the second switch circuit SW2 are each formed based on an element having low power consumption, e.g. a C-MOS.

The traveling contacts of the first and second switch circuits SW1, SW2 are connected with a selecting part 20. In the case of the embodiment, the selecting part 20 includes a pair of AND circuits 22, 24, an inverter 26, and a selection-setting part 28. One AND circuit 22 has an output terminal connected to the traveling contact of the first switch circuit SW1. Also, the AND circuit 22 has one input terminal connected to an output terminal of the inverter 26, and the other input terminal connected to a setting-cancel part 30 provided outside the signal-selecting circuit 10. And, an input terminal of the inverter 26 is connected to the selection-setting part 28. The other AND circuit 24 has an output terminal connected to the traveling contact of the second switch circuit SW2. The AND circuit 24 has one input terminal connected to the selection-setting part 28 and the other input terminal connected to the setting-cancel part 30.

While the details are to be described later, the selection-setting part 28 is set so as to output “0” in response to a setting signal from the outside when it is applied to a low-active electronic circuit, and is set so as to output “1” when it is applied to a high-active electronic circuit. The setting-cancel part 30 is arranged so as to output “1” normally. When a cancel-command signal is input from the outside, the setting-cancel part 30 outputs “0” to turn the switch circuits SW1 and SW2 from ON to OFF state. Now, it is noted that the setting-cancel part 30 may be provided inside the selecting part 20.

Effects of the first embodiment arranged as described above are as follows. The setting-cancel part 30 provided outside the signal-selecting circuit 10 outputs “1” normally. In the case where the signal-selecting circuit 10 is applied to a low-active electronic circuit in which low voltage level's state of a signal input from the input port 12 is regarded as “1,” i.e. an electronic circuit that works according to negative logic, the signal-selecting circuit 10 is set so that the selection-setting part 28 in the selecting part 20 outputs “0” when receiving a setting signal. The “0” that the selection-setting part 28 outputs is input to the inverter 26 and is supplied to the one input terminal of the AND circuit 24 concurrently. The inverter 26 inverts the input “0” thereby to output “1”, and then inputs the signal to the one input terminal of the AND circuit 22. The AND circuit 22 outputs “1” and turns on the first switch circuit SW1 of the pull-up circuit 16 because the “1” that the setting-cancel part 30 outputs is input to the other input terminal of the AND circuit 22.

On the other hand, the, “0” that the selection-setting part 28 outputs is input to the one input terminal of the AND circuit 24. Hence, the AND-circuit 24 outputs “0” and maintains the second switch circuit SW2 in the pull-down circuit 18 in its OFF state. As a result, the input port 12 of the signal-selecting circuit 10 is connected to the power source Vdd through the pull-up circuit 16, and the potential is fixed at High. When a low voltage level signal “L” is input to the input port 12 from an external electronic system, etc., a current flows from the power source Vdd to the external system through the pull-up circuit 16 and input port 12, the potential at the input port 12 lowers, whereby an input signal “L” flows through the signal line 14 and is input to the low-active electronic circuit.

When the signal-selecting circuit 10 is applied to a high-active electronic circuit, i.e. an electronic circuit that works according to the positive logic, the selection-setting part 28 in the selecting part 20 is set so as to output “1”. Thus, the “0” that the inverter 26 outputs is input to the one input terminal of the AND circuit 22 and. as such, the AND circuit 22 outputs “0,” whereby the first switch circuit SW1 of the pull-up circuit 16 is maintained in its OFF state. The other AND circuit 24 outputs “1” and turns on the second switch circuit SW2 of the pull-down circuit 18 because the “1” output by the selection-setting part 28 and the “1” output by the setting-cancel part 30 are input to the two input terminals of the AND circuit 24. As a result, the input port 12 of the signal-selecting circuit 10 is connected to the ground through the pull-down circuit 18 and the potential is fixed at Low. When a signal of a high voltage level “H” is input to the input port 12 from the outside, a current flows to the ground through the pull-down circuit 18, an input signal “H” proportional to the voltage across the second resistor R2 in the pull-down circuit 18 passes through the signal line 14 and is supplied to the high-active electronic circuit.

In the case where the signal from the outside, which is input to the input port 12, is a control signal for the switch, etc. and it is required only to sense the input signal like e.g. a process-starting command or process-termination command for an electronic circuit connected to the signal line 14 or a device-activation command, a cancel-command signal is input to the setting-cancel part 30 from e.g. CPU (not shown) immediately after the input signal is sensed. The setting-cancel part 30 outputs “0” when a setting-cancel signal is input. Therefore, the output of AND circuits 22, 24 in the selecting part 20 is made “0,” whereby the first switch circuit SW1 of the pull-up circuit 16 or the second switch circuit SW2 of the pull-down circuit 18, which has been in ON state, is turned off. Thus, even when the situation where the switch is depressed for a long time needlessly, a system problem, or the like causes the first switch circuit SW1 or the second switch circuit SW2 to be left ON for a long time, a current flowing through the resistor R1 or R2 can be cut off, and therefore earlier battery drain in a portable system such as a cellular phone can be prevented. In this case, the setting-cancel part 30 may be arranged so that it automatically outputs “1” at the time when a given length of time has elapsed after the output of a cancel signal “0.”

The signal-selecting circuit 10 of the first embodiment can selectively perform the following operations in this way: turning on the first switch circuit SW1 to fix the potential of the input port 12 at High; and turning on the second switch circuit SW2 to fix the potential of the input port 12 at Low. Hence, the signal-selecting circuit 10 can cope with both a low-active electronic circuit and a high-active electronic circuit, and can provide an input port with high general versatility.

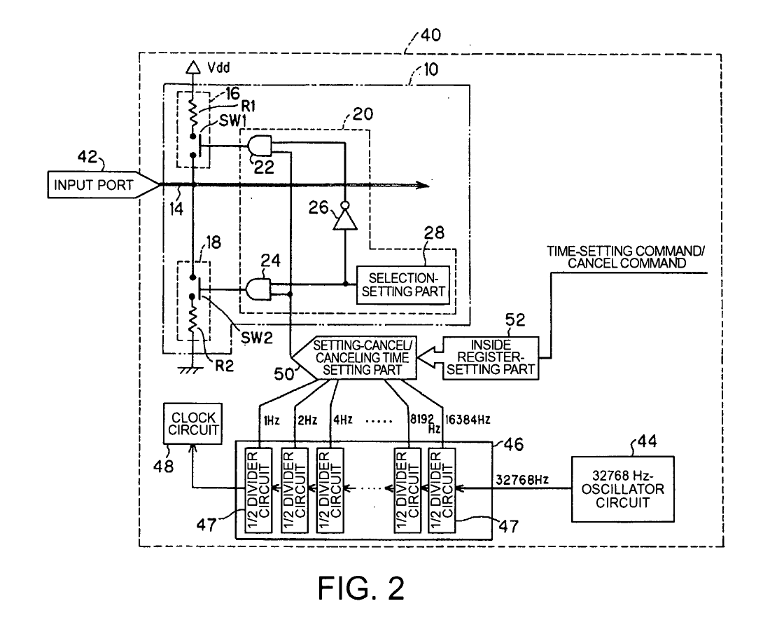

FIG. 2 is a view of assistance in explaining the second embodiment, and specifically a block diagram showing a part of a real time clock device with the above-described signal-selecting circuit. As in FIG. 2, the real time clock device 40 has a signal-selecting circuit 10 connected to a input port 42, an oscillator circuit 44 that outputs a clock signal of 32768 Hz (an original oscillation clock signal), a divider part 46, a clock circuit 48, a setting-cancel/canceling time setting part 50, inside register-setting part 52, etc. In the signal-selecting circuit 10, the pull-up circuit 16 and pull-down circuit 18 are connected to an input port 42 through a signal line 14. The other input terminals of the AND circuits 22, 24 included in a selecting part 20 of the signal-selecting circuit 10 are connected to the output side of the setting-cancel/canceling time setting part 50, the detail of which is to be described later.

The oscillator circuit 44 includes a piezoelectric resonator (quartz oscillator in this case), which is not shown in the drawing. In the case of the embodiment, the oscillator circuit 44 outputs an original oscillation clock signal of 32768 Hz to the divider part 46 provided on the output side thereof. The divider part 46 is capable of outputting an original oscillation clock signal of 32768 Hz input from the oscillator circuit 44 directly, and includes two or more ½ divider circuits 47. The divider circuits 47 are connected so as to form multiple stages. The input original oscillation clock signal of 32768 Hz is sequentially subjected to ½ division stepwise, whereby a one-second signal of 1 Hz is produced. Then, the divider part 46 outputs the clock signal of 1 Hz (one-second signal) to the clock circuit 48 in the real time clock device 40, and outputs clock signals of different cycles resulting from the division in the individual ½ divider circuits 47 to the setting-cancel/canceling time setting part 50. In addition, the setting-cancel/canceling time setting part 50 is connected with the inside register-setting part 52.

The setting-cancel/canceling time setting part 50 outputs “1” normally, and the output is supplied to the other input terminals of the AND circuits 22, 24 included in the selecting part 20 of the signal-selecting circuit 10. Also, the setting-cancel/canceling time setting part 50 includes a delay circuit (not shown). When the electronic circuit detects an input signal and outputs a setting-cancel command, the setting-cancel/canceling time setting part 50 outputs a cancel signal “0” to turn off the first switch circuit SW1 or the second switch circuit SW2 a given length of time later as described later. The delay circuit provided in the setting-cancel/canceling time setting part 50 is arranged so that it counts clock signals output by the divider part 46 thereby to obtain a setting-cancel time, i.e. delay time. The delay time is set by the inside register-setting part 52.

The inside register-setting part 52 is arranged so that it receives a time-setting command signal and a cancel-command signal from an electronic circuit such as CPU. When the inside register-setting part 52 receives a time-setting command signal, it sets an address in the setting,-cancel/canceling time setting part 50 so that of clock signals output by the divider part 46, a clock signal of a cycle adequate to produce the specified delay time is input to the delay circuit of the setting-cancel/canceling time setting part 50 according to the time specified by the command signal. Also, when an electronic circuit such as a CPU senses that a signal is input to the input port 42 of the real time clock device 40 and a cancel signal output by the electronic circuit is input to the inside register-setting part 52, the inside register-setting part 52 activates the delay circuit of the setting-cancel/canceling time setting part. When the measurement of the delay time set for the delay circuit (counting of clock signals output by the divider part 46) is terminated, the setting-cancel/canceling time setting part 50 outputs “0” and supplies it to the AND circuits 22, 24 included in the selecting part 20 of the signal-selecting circuit 10. This causes the AND circuit 22 or the AND circuit 24 to turn the first switch circuit SW1 or the second switch circuit SW2 from ON to OFF state.

In this way, in the real time clock device 40 in association with the second embodiment, when a signal is input to the input port 42, the electronic circuit detects the input signal. Then, a given length of time later, the real time clock device 40 cuts off the input signal and concurrently outputs the signal as an interrupt signal to the CPU, etc. The interrupt signal can be applied to various kinds of electronic circuits and electronic systems. For example, in the case where a signal to turn off a stepping motor is input, a CPU recognizes the OFF signal a certain length of time later than input of the OFF signal, whereby the stepping motor can be rotated by a given number of steps.

However, using a cancel signal to turn off the switch circuit and thereby release the resistance may bring the input port 42 into high impedance condition, which makes the input potential unstable. Such condition leads to the occurrence of a flow-through current in a C-MOS element of the switch circuit, resulting in an increase in electric current consumption. To avoid such condition, the setting not to intentionally release the resistance may be made.

In addition to this, the input port 42 may be connected to a common bus line that the CPU has. In this case, turning off both the switch circuits SW1 and SW2 can make the potential of the bus line unstable, which causes malfunction of peripheral components connected to the bus line. Therefore, to prevent the malfunction of peripheral components, the potential of the bus line must be fixed at High or Low. However, in the same way even in such case, the malfunction of peripheral components can be prevented by turning on the switch circuit SW1 or SW2 to maintain the input port 42 at High or Low.

Besides, in this embodiment, the time of-delay caused by the setting-cancel/canceling time setting part 50 is measured based on clock signals output by the divider part 46, which differ in cycle mutually, and therefore a desired delay time can be set readily and correctly by arbitrarily selecting a used clock signal. Also, in the embodiment, the time measurement is made based on clock signals output by the oscillator circuit 44 having a quartz oscillator and as such, the accuracy of set delay time can be improved greatly in comparison to time measurement by software processing. Besides, the delay time is measured using clock signals output by the oscillator circuit 44 that the real time clock device incorporates therein and as such, there is no need to provide an oscillator circuit particularly for the time measurement for the delay circuit. Therefore, the real time clock device 40 can be manufactured at a low cost and the power consumption thereof is not increased.

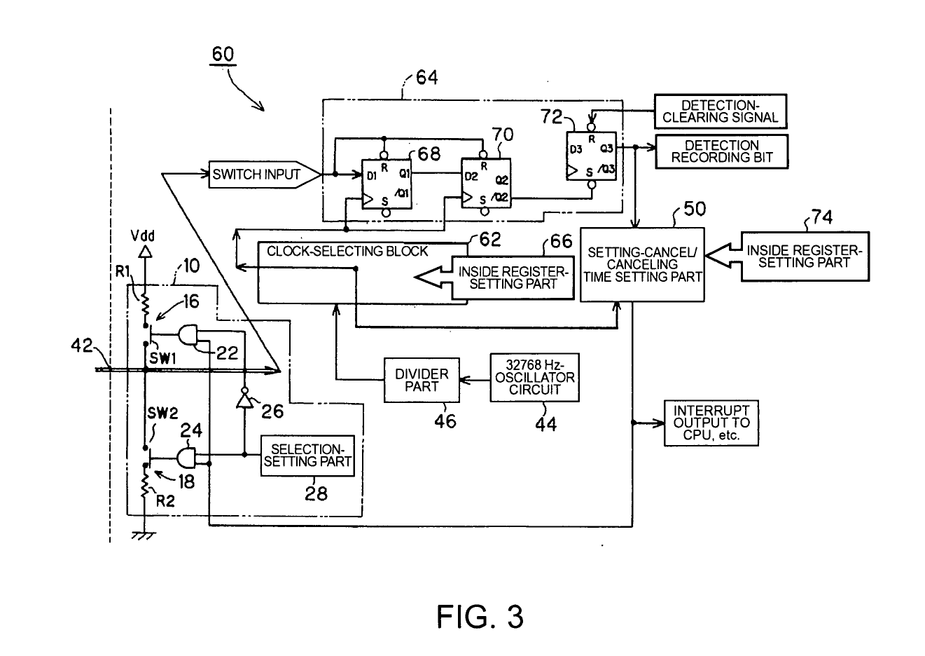

FIG. 3 is a view of assistance in explaining the third embodiment, which shows another embodiment of the real time clock device. As in FIG. 3, a real time clock device 60 in association with the third embodiment includes a signal-selecting circuit 10 connected to the input port 42. Also, the real time clock device 60 has a clock-selecting block 62 provided on the output side of the divider part 46 and a switch input-detection circuit 64 connected on the output side of the clock-selecting block 62. Further, the clock-selecting block 62 is connected with the inside register-setting part 66. The inside register-setting part 66 selects and sets a register in the clock-selecting block 62 on receipt of a setting signal from e.g. a CPU so that the clock-selecting block 62 outputs a selected arbitrary clock signal, of clock signals output by the divider part 46.

In this embodiment, the switch input-detection circuit 64 includes three flip-flops 68, 70, 72. The flip-flops 68, 70 constitute a serial in and serial out type shift register, in which an output terminal Q1 of the flip-flop 68 is connected to an input terminal D2 of the flip-flop 70. An output terminal of the clock-selecting block 62 is connected to clock terminals of the flip-flops 68, 70, whereby the clock-selecting block 62 is arranged so as to supply a clock signal to the clock terminals of the flip-flops 68, 70 concurrently. Reset terminals R of the flip-flops 68, 70 and an input terminal D1 of the flip-flop 68 are arranged so as to accept a switch input (signal) input to the input port 42 of the real time clock device 60.

The flip-flop 72 includes a set terminal S and a reset terminal R. The set terminal S is connected to an output terminal /Q2 of the flip-flop 70. Also, the flip-flop 72 is arranged so as to receive a detection-clearing signal from e.g. a CPU (not shown) through its reset terminal R. Further, an output terminal Q3 of the flip-flop 72 makes an output terminal of the switch input-detection circuit 64. As described later, when a signal of a given length or longer is input to the input port 42, the signal is regarded as an input signal resulting from an operation of depressing, a switch (not shown), the switch input-detection circuit 64 outputs a detection signal (detection-recording bit) through an output terminal Q3 to e.g. the CPU. The detection signal output from the output terminal Q3 of the flip-flop 72 is input to the setting-cancel/canceling time setting part 50 as a cancel-command signal. Incidentally, the flip-flops 68, 70, 72 are arranged so that their set terminals S and reset terminals R work according to the negative logic. Also, the flip-flops 68, 70, 72 are arranged so that they work during a period of time corresponding to the leading edge of a clock signal input to the clock input terminal.

The setting-cancel/canceling time setting part 50 has a delay circuit as in the case of the above embodiment, and delays a cancel-command signal input from the flip-flop 72 by a given length of time to output a cancel signal “0”. In the case of this embodiment, an output signal of the setting-cancel/canceling time setting part 50 is supplied as an interrupt signal to e.g. CPU. Further, a clock signal output by the clock-selecting block 62 is input to the setting-cancel/canceling time setting part 50. Also, the setting-cancel/canceling time setting part 50 is connected to an inside register-setting part 74. The inside register-setting part 74 receives a time-setting command signal from e.g. the CPU and sets a delay time measured by the delay circuit provided in the setting-cancel/canceling time setting part 50. Incidentally, a clock signal that the clock-selecting block 62 outputs to the switch input-detection circuit 64 and a clock signal that the block 62 outputs to the setting-cancel/canceling time setting part 50 may have cycles differing from each other, or may be of the same cycle.

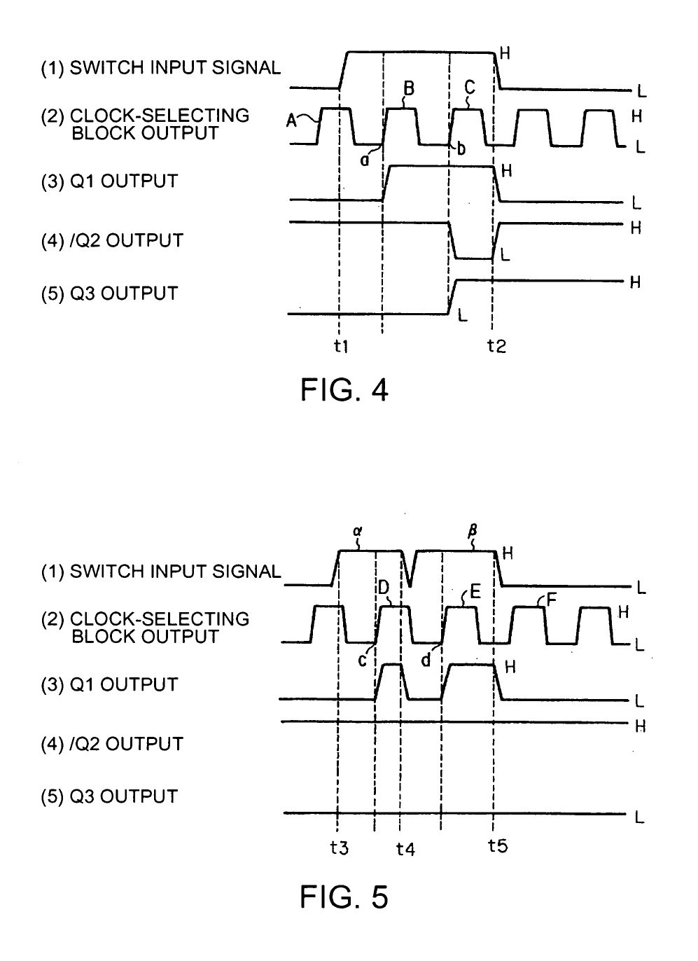

The switch input-detection circuit 64 of the real time clock device 60 arranged as described above detects, as a switch input signal, a signal input to the input port 42 in the case where the signal input to the input port 42 has a length representing a length of time during which leading edges of two successive clock signals output by the clock-selecting block 62 can be input as shown in FIGS. 4 and 5. Hence, it is possible to absorb (or remove) noise such as chattering caused when the switch is depressed, and the switch input-detection circuit 64 can detect only a signal resulting from depression of the switch reliably. Therefore, it is possible to prevent malfunction of an electronic device and the like.

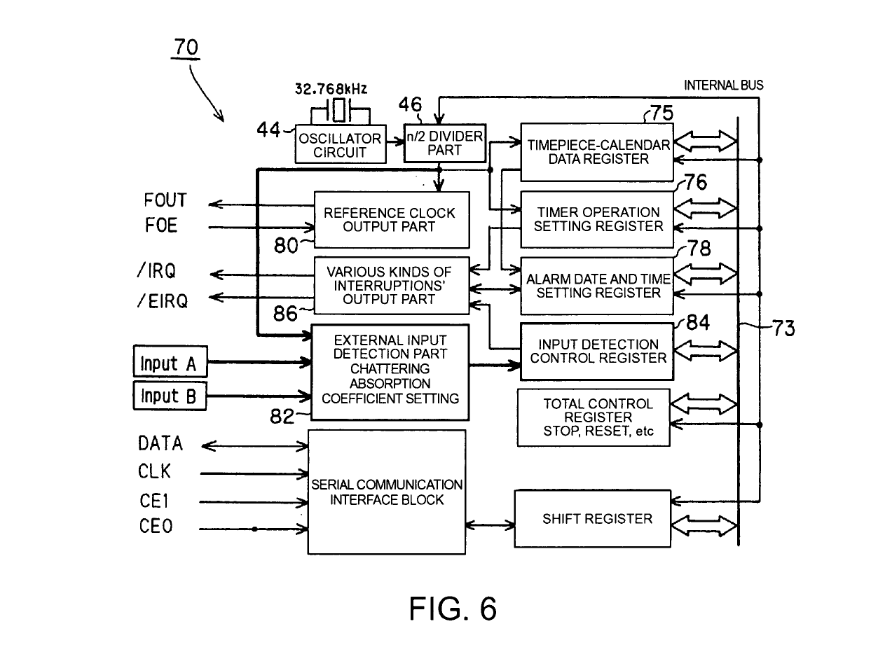

FIG. 6 is an entire block diagram showing an example of a real time clock device in association with the embodiment. As in FIG. 6, the real time clock device 70 includes an oscillator circuit 44 that outputs an original oscillation clock signal of 32768 Hz, and a divider part 46, which has ½ divider circuits connected so as to form multiple stages, converts original oscillation clock signals output by the oscillator circuit 44 into clock signals with different cycles, and outputs a one-second signal of 1 Hz. The one-second signal output by the divider part 46 is supplied through an internal bus 73 to a timepiece-calendar data register 75, a timer operation setting register 76, an alarm date and time setting register 78, etc. Also, a clock signal output by the divider part 46 is supplied to a reference clock output part 80 and an external input detection part 82.

The external input detection part 82 includes two or more input ports (Input A and Input B in the embodiment), and the signal-selecting circuit 10, the switch input-detection circuit 64, and the setting-cancel/canceling time setting part 50 shown in FIG. 3. When the external input detection part 82 detects an input signal such as a switch input, it outputs the detection signal to an input detection control register 84. The input detection control register 84 holds a detection signal output by the external input detection part 82, sends an output to a various kinds of interruptions' output part 86, and through the internal bus 73 to a CPU, etc.

1. A signal-selecting circuit comprising:
a pull-up circuit having a first resistive element and a first switch part connected in series with the first resistive element, and one end connected to an input terminal of an electronic circuit and another the other end connected to a power source;
a pull-down circuit having a second resistive element and a second switch part connected in series with the second resistive element, and one end connected to the input terminal and another end connected to a ground; and
a selecting part that turns on one of the first switch part and the second switch part depending on a selecting signal input thereto.

2. The signal-selecting circuit of claim 1, wherein the selecting part is connected to a setting-cancel part that outputs a cancel signal serving to turn off the one of the first and second switch part, which has been turned on, according to an input-sensing signal issued when the electronic circuit senses a signal input to the input terminal.

3. The signal-selecting circuit of claim 2, wherein the setting-cancel part has a delay circuit that delays the input-sensing signal output by the electronic circuit by a predetermined length of time to output the cancel signal.

4. The signal-selecting circuit of claim 3, wherein the delay circuit delays the input-sensing signal input therein to output the cancel signal based on a clock signal output by an oscillator circuit of the electronic circuits.

5. A real time clock device comprising:
the signal-selecting circuit of claim 1; and
an oscillator circuit.

6. The real time clock device of claim 5, comprising:
a divider part that converts an original oscillation clock signal output by the oscillator circuit into clock signals differing in cycle from each other and outputs the clock signals; and
a clock signal selecting part provided on an output side of the divider part, which outputs a clock signal of an arbitrary cycle output by the divider part to the delay circuit based on an input clock-selecting signal.
